(19) United States
(12) Patent Application Publication
(10) Pub. No.: US 2026/0282234 A1
(43) Pub. Date: Sep. 17, 2026

(54) SWITCHING POWER SUPPLY MODULE

(71) Applicant: Murata Manufacturing Co., Ltd., Kyoto-fu (JP)

(72) Inventors: Kiyokazu YAMADA, Nagaokakyo-shi (JP); Tatsuya HOSOTANI, Nagaokakyo-shi (JP)

(73) Assignee: Murata Manufacturing Co., Ltd., Kyoto-fu (JP)

(21) Appl. No.: 19/668,219

(22) Filed: May 5, 2026

Related U.S. Application Data
(63) Continuation of application No. PCT/JP2024/029237, filed on Aug. 19, 2024.

(30) Foreign Application Priority Data
Nov. 7, 2023 (JP) 2023-190061

(51) Int. Cl. H05K 1/181; H02M 3/00; H02M 3/158; H05K 1/11

(52) U.S. Cl. CPC H05K 1/181; H02M 3/003; H05K 1/111; H02M 3/1586; H05K 2201/042; H05K 2201/10015; H05K 2201/1003; H05K 2201/10053

(57) ABSTRACT

A switching power supply module includes a circuit board on which a switching element is mounted, a circuit board on which at least one of an input capacitor element and an output capacitor element is mounted, and a power inductor element that electrically connects the switching element and the output capacitor. The power inductor element is between the circuit board and the circuit board. The power inductor element includes a metal conductor and a core magnetic material, the magnetic core encloses the metal conductor, and in an enclosed portion the metal conductor and the magnetic core are in close contact with each other to form a closely contacting structure. The metal conductor includes a main body portion enclosed in the magnetic core.

### CROSS-REFERENCE TO RELATED APPLICATIONS

This application claims benefit of priority to International Patent Application No. PCT/JP2024/029237, filed Aug. 19, 2024, and to Japanese Patent Application No. 2023-190061, filed Nov. 7, 2023, the entire contents of each are incorporated herein by reference.

### BACKGROUND

### Technical Field

The present disclosure relates to a switching power supply module provided with a plurality of power conversion circuits.

### Background Art

In general, a conventional switching power supply device has a structure in which switching elements, inductors, and capacitors that constitute a power conversion circuit are mounted on one side of a printed circuit board.

Currently, driving advanced processors requires the supply of high current. Examples of the advanced processors are advanced semiconductor integrated circuits (ICs) that perform high-speed computations used in artificial intelligence (AI) and data centers. With semiconductor process scaling, the operating voltage of advanced processors has decreased, and it has become necessary to supply advanced processors with low-voltage, high-current power.

To achieve such high-current operation, there has been a demand for a switching power supply device in which a plurality of power conversion circuits are connected in parallel.

As such a switching power supply device, U.S. Pat. No. 11,282,632 describes a power supply module provided with a first circuit board, a second circuit board, and a magnetic core module.

The first circuit board includes at least one power circuit. The second circuit board includes at least an output capacitor. The first circuit board and the second circuit board are spaced apart.

A rod-shaped conductor is mounted on the surface of the first circuit board that is closer to the second circuit board.

A magnetic core module is disposed between the first circuit board and the second circuit board. The magnetic core module has a through hole formed therein. The rod-shaped conductor is inserted through this through hole to form the output inductor of the power supply module.

### SUMMARY

However, in the power supply module described in U.S. Pat. No. 11,282,632, it is difficult to physically fix the magnetic core module, and the rigidity of the module structure is low. It is also difficult to align the first circuit board, the second circuit board, and the magnetic core module, and the manufacturing of the power supply module is complicated.

In addition, since the power supply module is configured such that the conductor is inserted through the through hole of the magnetic core module, an unavoidable gap exists between the magnetic core module and the conductor. Consequently, leakage magnetic flux during switching operation increases, inductance decreases, and power conversion efficiency decreases. Furthermore, electromagnetic noise is radiated, and problems of electromagnetic interference become apparent.

Accordingly, the present disclosure provides a switching power supply module that improves the rigidity of the module structure, that is easy to manufacture, and that achieves high power conversion efficiency and suppression of electromagnetic noise and electromagnetic interference.

A switching power supply module according to an embodiment of this disclosure includes a first circuit board on which a switching element is mounted, a second circuit board on which at least one of an input capacitor and an output capacitor is mounted, and a power inductor that electrically connects the switching element and the output capacitor.

The power inductor is disposed between the first circuit board and the second circuit board. The power inductor includes a metal conductor and a magnetic core, the magnetic core encloses the metal conductor, and in an enclosed portion the metal conductor and the magnetic core are in close contact with each other to form a closely contacting structure.

The metal conductor includes a main body portion that is enclosed in the magnetic core, a first end portion that is not enclosed in the magnetic core and forms a first terminal of the power inductor at one end of the main body portion, and a second end portion that is not enclosed in the magnetic core and that forms a second terminal of the power inductor at another end of the main body portion.

The first end portion extends from the main body portion to the first circuit board and is physically and electrically connected to the first circuit board. The second end portion extends from the main body portion to the second circuit board and is physically and electrically connected to the second circuit board.

A structure in which the first end portion of the power inductor is connected to the first circuit board and a structure in which the second end portion of the power inductor is connected to the second circuit board constitute a three-dimensional structure in which a volumetric packing density of electronic components is increased.

In this configuration, a direction of magnetic flux generated by the switching current is controlled, while increasing a mounting density of electronic components in a volume space by causing a closed current path through which a switching current flows to be substantially orthogonal to the first circuit board and the second circuit board and causing a magnetic flux loop generated by the switching current to be substantially parallel to the first circuit board and the second circuit board.

This disclosure makes it possible to improve the rigidity of the module structure, achieve easy manufacturing and high power conversion efficiency, and suppress electromagnetic noise and electromagnetic interference.

### BRIEF DESCRIPTION OF THE DRAWINGS

FIG. 1 is a circuit diagram of a switching power supply module according to a first embodiment;

FIG. 2 is an external perspective view of the switching power supply module according to the first embodiment;

FIG. 3 is an exploded perspective view of the switching power supply module according to the first embodiment;

FIG. 4 includes a top view and a side view of the switching power supply module according to the first embodiment;

FIG. 5 includes a perspective view, a top view, and a side view of an inductor element of the switching power supply module according to the first embodiment;

FIG. 6A is a simplified and schematic perspective view of magnetic flux at a certain timing at which switching current flows in the inductor element, and FIG. 6B is a simplified and schematic perspective view of magnetic flux in the switching power supply module at that timing;

FIG. 7 is an external perspective view of a switching power supply module according to a second embodiment;

FIG. 8 includes a top view and a side view of the switching power supply module according to the second embodiment;

FIG. 9 is a side view of a switching power supply module according to a third embodiment;

FIG. 10 is a circuit diagram of a switching power supply module according to a fourth embodiment;

FIG. 11 is an exploded perspective view of the switching power supply module according to the fourth embodiment;

FIG. 12A and FIG. 12B are plan views of a circuit board according to the fourth embodiment, and FIG. 12C is a side view of the switching power supply module according to the fourth embodiment;

FIG. 13A is an external perspective view of an inductor element according to the fourth embodiment, and FIG. 13B includes four views thereof; and

FIG. 14 is an exploded perspective view of a switching power supply module according to a fifth embodiment.

### DETAILED DESCRIPTION

### First Embodiment

A switching power supply module according to a first embodiment of the present disclosure will be described with reference to the drawings.

### (Circuit Configuration of Switching Power Supply Module 10)

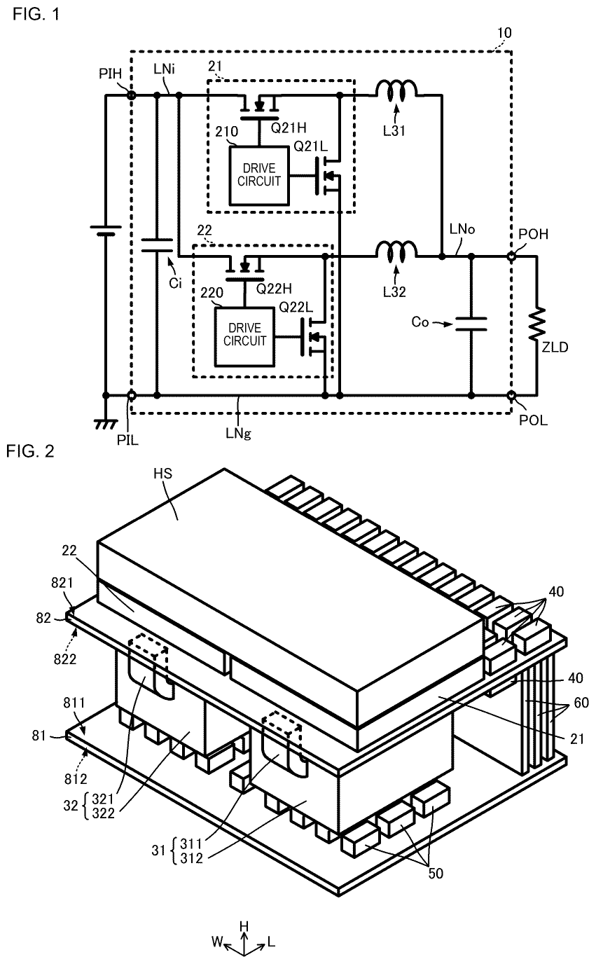

FIG. 1 is a circuit diagram of a switching power supply module according to the first embodiment. As illustrated in FIG. 1, a switching power supply module 10 includes a plurality of power semiconductor package devices (a power semiconductor package device 21 and a power semiconductor package device 22), a plurality of inductors (an inductor L31 and an inductor L32: power inductors), an input capacitor Ci, and an output capacitor Co.

The switching power supply module 10 includes a pair of input terminals PIH and PIL, a pair of output terminals POH and POL, an input-side wiring line LNi, an output-side wiring line LNo, and a reference potential wiring line LNg.

A direct current (DC) power supply is connected to the input terminal PIH and the input terminal PIL. The input terminal PIH is connected to the positive terminal of the DC power supply, and the input terminal PIL is connected to the negative terminal of the DC power supply. The input capacitor Ci is connected between the input terminal PIH and the input terminal PIL. The input-side wiring line LNi is connected to the input terminal PIH, and the reference potential wiring line LNg is connected to the input terminal PIL.

The power semiconductor package device 21 and the power semiconductor package device 22 are each connected to the input terminal PIH and the input terminal PIL.

The power semiconductor package device 21 includes a drive circuit 210, a power semiconductor device Q21H, and a power semiconductor device Q21L. The drive circuit 210 includes analog circuits. The power semiconductor device Q21H and the power semiconductor device Q21L include, for example, a power field-effect transistor (FET). The drive circuit 210, the power semiconductor device Q21H, and the power semiconductor device Q21L are formed as a single analog integrated circuit (IC).

The drain terminal of the power semiconductor device Q21H is connected to the input-side wiring line LNi. The source terminal of the power semiconductor device Q21H is connected to the drain terminal of the power semiconductor device Q21L. The source terminal of the power semiconductor device Q21L is connected to the reference potential wiring line LNg.

The gate terminal of the power semiconductor device Q21H and the gate terminal of the power semiconductor device Q21L are connected to the drive circuit 210. The drive circuit 210 receives power from the DC power supply through the input-side wiring line LNi, which is not illustrated in the drawing. The drive circuit 210 drives and controls the power semiconductor device Q21H and the power semiconductor device Q21L. As a result, the power semiconductor device Q21H and the power semiconductor device Q21L are subjected to switching control at a predetermined switching frequency (switching period).

The power semiconductor package device 22 includes a drive circuit 220, a power semiconductor device Q22H, and a power semiconductor device Q22L. The drive circuit 220 includes analog circuits. The power semiconductor device Q22H and the power semiconductor device Q22L include, for example, a power FET. The drive circuit 220, the power semiconductor device Q22H, and the power semiconductor device Q22L are formed as a single analog IC.

The drain terminal of the power semiconductor device Q22H is connected to the input-side wiring line LNi. The source terminal of the power semiconductor device Q22H is connected to the drain terminal of the power semiconductor device Q22L. The source terminal of the power semiconductor device Q22L is connected to the reference potential wiring line LNg.

The gate terminal of the power semiconductor device Q22H and the gate terminal of the power semiconductor device Q22L are connected to the drive circuit 220. The drive circuit 220 receives power from the DC power supply through the input-side wiring line LNi, which is not illustrated in the drawing. The drive circuit 220 drives and controls the power semiconductor device Q22H and the power semiconductor device Q22L. As a result, the power semiconductor device Q22H and the power semiconductor device Q22L are subjected to switching control at a predetermined switching frequency (switching period).

One terminal of the inductor L31 is connected to the output terminal of the power semiconductor package device 21 (the source terminal of the power semiconductor device Q21H and the gate terminal of the power semiconductor device Q21L).

One terminal of the inductor L32 is connected to the output terminal of the power semiconductor package device 22 (the source terminal of the power semiconductor device Q22H and the gate terminal of the power semiconductor device Q22L).

The other terminal of the inductor L31 and the other terminal of the inductor L32 are connected to the output-side wiring line LNo.

The output-side wiring line LNo is connected to the output terminal POH. The output terminal POL is connected to the reference potential wiring line LNg. The output capacitor Co is connected between the output terminal POH and the output terminal POL. A load ZLD is connected between the output terminal POH and the output terminal POL.

With this configuration, the switching power supply module 10 includes a first power conversion circuit and a second power conversion circuit. The first power conversion circuit includes the power semiconductor package device 21, the inductor L31, and the output capacitor Co. The second power conversion circuit includes the power semiconductor package device 22, the inductor L32, and the output capacitor Co.

The drive circuit 210 of the power semiconductor package device 21 and the drive circuit 220 of the power semiconductor package device 22 are connected to a microprocessing unit (MPU) (not illustrated).

The MPU performs multiphase control on the power semiconductor package device 21 and the power semiconductor package device 22. In this case, the MPU performs two-phase multiphase control. As a result, in the switching power supply module 10, the first power conversion circuit and the second power conversion circuit perform multiphase operation to supply power to the load ZLD.

### (Structure of Switching Power Supply Module 10)

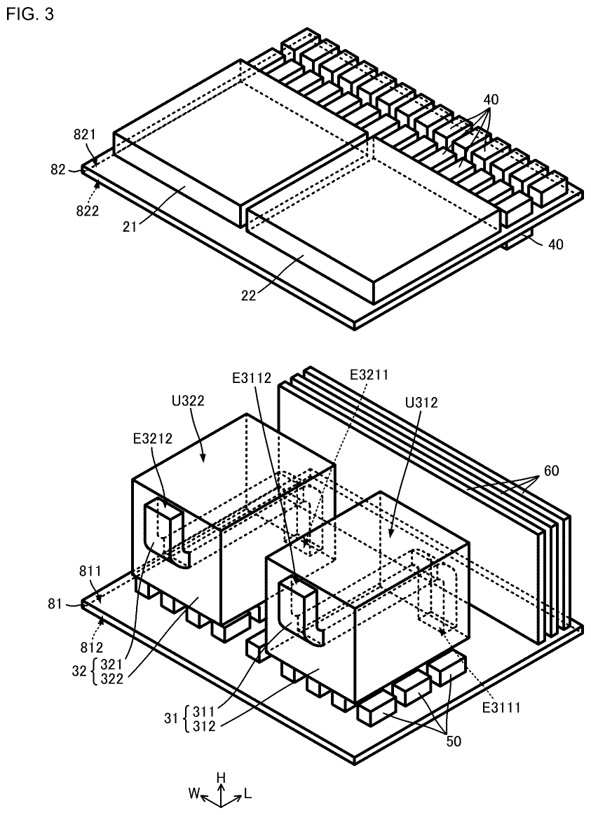

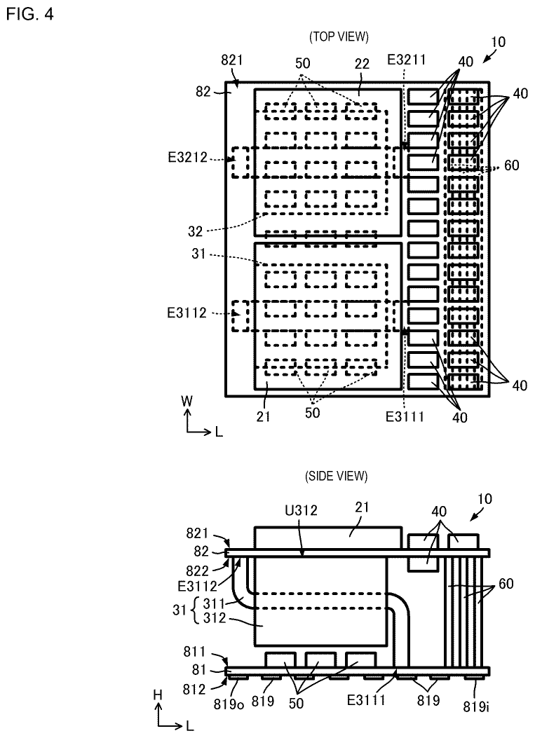

FIG. 2 is an external perspective view of the switching power supply module according to the first embodiment. FIG. 2 is a diagram in which a heat sink is attached to the switching power supply module. FIG. 3 is an exploded perspective view of the switching power supply module according to the first embodiment. FIG. 4 includes a top view and a side view of the switching power supply module according to the first embodiment.

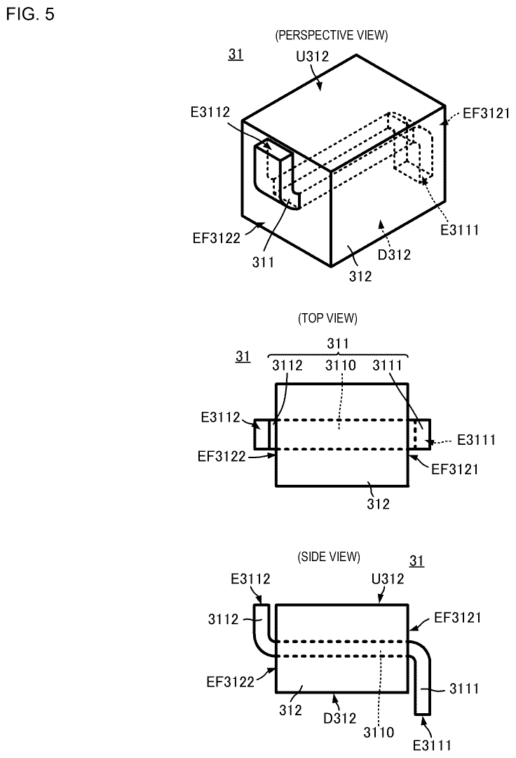

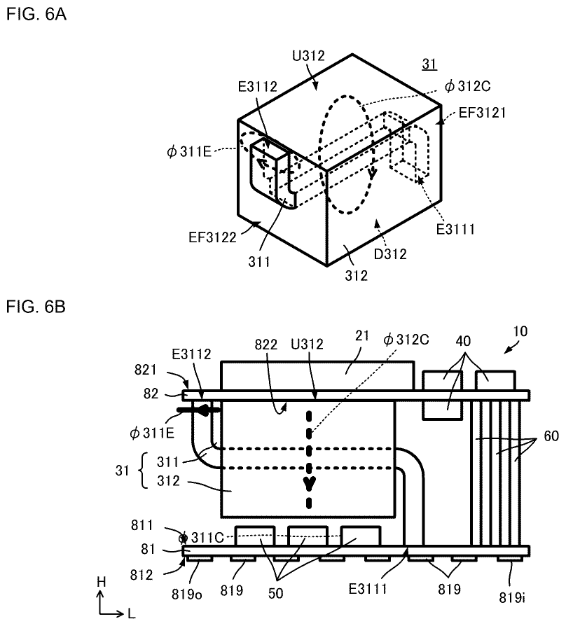

FIG. 5 includes a perspective view, a top view, and a side view of an inductor element of the switching power supply module according to the first embodiment. FIG. 6A is a simplified and schematic perspective view of magnetic flux at a certain timing at which switching current flows in the inductor element. FIG. 6B is a simplified and schematic side view of magnetic flux in the switching power supply module 10 at that timing.

In each of the drawings of the respective embodiments, including the present embodiment, leader lines and reference numerals are appropriately omitted for improved visibility to the extent that they can be readily inferred from the description of other portions.

The switching power supply module 10 includes a plurality of power semiconductor package devices 21 and 22, a plurality of inductor elements 31 and 32, a plurality of capacitor elements 40, a plurality of capacitor elements 50, a plurality of connection conductors 60, a circuit board 81, a circuit board 82, and a heat sink HS.

The power semiconductor package devices 21 and 22 are mountable analog ICs and correspond to the power semiconductor package devices 21 and 22 in the circuit diagram in FIG. 1, respectively.

The inductor element 31 and the inductor element 32 are mountable elements. The inductor element 31 corresponds to the inductor L31 in the circuit diagram in FIG. 1, and the inductor element 32 corresponds to the inductor L32 in the circuit diagram in FIG. 1. Although FIG. 5 illustrates the inductor element 31, the inductor element 31 and the inductor element 32 have the same structure.

As illustrated in FIG. 5, the inductor element 31 has a metal conductor 311 and a magnetic core 312. The metal conductor 311 is a rod having bent portions (curved portions) at intermediate positions. The metal conductor 311 has a main body portion 3110, a first end portion 3111, and a second end portion 3112.

The first end portion 3111 is connected to one end of the main body portion 3110 in its extension direction (conduction direction into the magnetic core 312). The second end portion 3112 is connected to the other end of the main body portion 3110 in its extension direction. The extension direction of the first end portion 3111 and that of the second end portion 3112 are orthogonal to that of the main body portion 3110. The extension direction of the first end portion 3111 and that of the second end portion 3112 are opposite to each other. The tip portion (the end portion on the opposite side from the end portion connected to the main body portion 3110) of the first end portion 3111 is a first terminal E3111 of the inductor element 31. The tip portion (the end portion on the opposite side from the end portion connected to the main body portion 3110) of the second end portion 3112 is a second terminal E3112 of the inductor element 31.

The magnetic core 312 has a substantially rectangular parallelepiped shape and encloses the main body portion 3110 of the metal conductor 311. The magnetic core 312 is in close contact with the side surfaces of the main body portion 3110 (in the penetration portion of the magnetic core 312 through which the main body portion 3110 penetrates, the surfaces of the main body portion 3110 parallel to the direction of penetration).

The first end portion 3111 protrudes from a first end surface EF3121 of the magnetic core 312 to the outside of the magnetic core 312 and extends to the side where a rear surface D312 of the magnetic core 312 is present. The tip (the first terminal E3111) of the first end portion 3111 protrudes beyond the rear surface D312 of the magnetic core 312.

The second end portion 3112 protrudes from a second end surface EF3122 of the magnetic core 312 to the outside of the magnetic core 312 and extends to the side where a front surface U312 of the magnetic core 312 is present. The tip (the second terminal E3112) of the second end portion 3112 is flush with the front surface U312 of the magnetic core 312.

Note that the shape of the inductor element 31 and that of the inductor element 32 are not limited to these as long as the first terminal E3111 is formed so as to protrude toward the rear surface D312 side of the magnetic core 312 and the second terminal E3112 is formed so as to be flush with the front surface U312 of the magnetic core 312.

The magnetic core 312 includes a first magnetic core portion and a second magnetic core portion. The first magnetic core portion covers the side surfaces of the main body portion 3110 and is in close contact with the main body portion 3110. The second magnetic core portion covers the external surface of the first magnetic core portion (the surfaces of the first magnetic core portion on the opposite side from the inner surface that is in close contact with the main body portion). The second magnetic core portion is spaced apart from the main body portion 3110 and is in close contact with the first magnetic core portion.

The first magnetic core portion and the second magnetic core portion have different material compositions. The first magnetic core portion has a composition that prioritizes the closeness of contact with the main body portion 3110, and the second magnetic core portion has a composition that prioritizes properties. The first magnetic core portion and the second magnetic core portion are formed as a single unit.

A magnetic core 322 has substantially the same configuration as the magnetic core 312.

The plurality of capacitor elements 40 are mountable elements. The plurality of capacitor elements 40 correspond to the input capacitor Ci in FIG. 1. The plurality of capacitor elements 40 are, for example, chip-type capacitor elements having terminals electrodes at both ends.

The plurality of capacitor elements 50 are mountable elements. The plurality of capacitor elements 50 correspond to the output capacitor Co in FIG. 1. The plurality of capacitor elements 50 are, for example, chip-type capacitor elements having terminals electrodes at both ends.

### (Mounting Structure of Circuit Board 81)

The circuit board 81 is substantially rectangular in plan view and has a front surface 811 and a rear surface 812. The circuit board 81 is mainly made of insulating resin, and has a conductor pattern formed thereon to realize the switching power supply module 10. In the present embodiment, the circuit board 81 corresponds to a second circuit board.

For example, as illustrated in FIGS. 3 and 4, the inductor element 31, the inductor element 32, the plurality of capacitor elements 50, and the plurality of connection conductors 60 are mounted on the front surface 811 of the circuit board 81. In other words, the front surface 811 is the mounting surface for the inductor element 31, the inductor element 32, the plurality of capacitor elements 50, and the plurality of connection conductors 60. More specifically, the mounting pattern is as follows.

The inductor element 31 and the inductor element 32 are mounted such that their respective length directions (the direction in which the main body portion 3110 of the metal conductor 311 extends and the direction in which a main body portion of a metal conductor 321 extends) are parallel to a first direction of the circuit board 81 (L direction in each diagram). The inductor element 31 and the inductor element 32 are mounted adjacent to each other in a second direction of the circuit board 81 (W direction in each diagram).

The inductor element 31 and the inductor element 32 are mounted such that the directions in which their main body portions extend are substantially parallel to the front surface 811 of the circuit board 81.

The inductor element 31 is mounted such that the magnetic core 312 is positioned away from the front surface 811. The inductor element 32 is mounted such that the magnetic core 322 is positioned away from the front surface 811. The distance between the magnetic core 312 and the front surface 811 is substantially the same as that between the magnetic core 322 and the front surface 811.

The first terminal E3111 of the metal conductor 311 of the inductor element 31 and a first terminal E3211 of the metal conductor 321 of the inductor element 32 are joined to land conductors on the front surface 811 of the circuit board 81 by solder or another conductive joining material.

The second terminal E3112 of the inductor element 31 and a second terminal E3212 of the inductor element 32 are located near one end of the circuit board 81 in the first direction.

The plurality of capacitor elements 50 are mounted between the magnetic core 312 of the inductor element 31 and the front surface 811 or between the magnetic core 322 of the inductor element 32 and the front surface 811 in the height direction (H direction in each diagram). The plurality of capacitor elements 50 are mounted in a region that substantially overlaps the inductor element 31 or the inductor element 32 when the front surface 811 is viewed in plan. The plurality of capacitor elements 50 are arranged in a two-dimensional array along two orthogonal axes in the first and second directions.

The plurality of connection conductors 60 are metal plates with planar surfaces or insulating substrates that have planar surfaces and on which conductor patterns are formed (for example, glass epoxy substrates). The length of the plurality of connection conductors 60 in the second direction (W direction) is substantially the same as that of the circuit board 81 and circuit board 82 in the second direction (W direction).

The plurality of connection conductors 60 are mounted on the front surface 811 and near the other end of the circuit board 81 in the first direction (L direction in each drawing). The plurality of connection conductors 60 are disposed such that their planar surfaces are parallel in the direction that is parallel to the direction orthogonal to the front surface 811 and that is parallel to the second direction (W direction in each drawing). The plurality of connection conductors 60 are disposed so as to be spaced apart from each other in the first direction.

A plurality of external connection conductors 819 are formed on the rear surface 812 of the circuit board 81. The plurality of external connection conductors 819 are circular in plan view, for example, and are arranged in a two-dimensional array along two orthogonal axes in the first and second directions. One or more of the plurality of external connection conductors 819 are used to form the input terminal PIH, the input terminal PIL, the output terminal POH, and the output terminal POL illustrated in the circuit in FIG. 1.

### (Mounting Structure of Circuit Board 82)

The circuit board 82 is substantially rectangular in plan view and has a front surface 821 and a rear surface 822. The circuit board 82 is mainly made of insulating resin, and has a conductor pattern formed thereon to realize the switching power supply module 10. The planar shape of the circuit board 82 is substantially the same as that of the circuit board 81. In the present embodiment, the circuit board 82 corresponds to a first circuit board.

For example, as illustrated in FIGS. 3 and 4, the power semiconductor package device 21, the power semiconductor package device 22, and a plurality of capacitor elements 40 are mounted on the front surface 821 of the circuit board 82. In other words, the front surface 821 is the mounting surface for the power semiconductor package device 21, the power semiconductor package device 22, and the plurality of capacitor elements 40.

The power semiconductor package device 21 and the power semiconductor package device 22 are aligned on the front surface 821 in the second direction (W direction in each drawing).

The pair of the power semiconductor package device 21 and the power semiconductor package device 22 and the group of the plurality of capacitor elements 40 are aligned on the front surface 821 in the first direction (L direction in each drawing). The pair of the power semiconductor package device 21 and the power semiconductor package device 22 is disposed closer to one end of the front surface 821 than the group of the plurality of capacitor elements 40 is.

The plurality of capacitor elements 40 are arranged in a two-dimensional array on the front surface 821 along two orthogonal axes in the first and second directions.

A plurality of capacitor elements 40 are mounted on the rear surface 822 of the circuit board 82. In other words, the rear surface 822 is the mounting surface for the plurality of capacitor elements 40. The plurality of capacitor elements 40 on the rear surface 822 are mounted on a region that overlaps the mounting region of the plurality of capacitor elements 40 on the front surface 821.

At one end of the rear surface 822 in the first direction, land conductors are formed on which the second terminal E3112 of the inductor element 31 and the second terminal E3212 of the inductor element 32 are to be mounted. At the other end of the rear surface 822 in the first direction, none of the plurality of capacitor elements 40 is mounted but land conductors (see the dotted lines in FIG. 4) are formed on which the plurality of connection conductors 60 are to be mounted. That is, the rear surface 822 is the mounting surface for the plurality of connection conductors 60, the second terminal E3112 of the inductor element 31, and the second terminal E3212 of the inductor element 32.

### (Multilayer Structure of Circuit Board 81 and Circuit Board 82)

The circuit board 82 is disposed on the front surface 811 side of the circuit board 81. The rear surface 822 of the circuit board 82 faces the front surface 811 of the circuit board 81. In other words, the circuit board 82 and the circuit board 81 overlap (in plan view) when viewed in the height direction (H direction in each drawing). The longitudinal direction of the circuit board 81 is parallel to that of the circuit board 82.

The circuit board 81 and the circuit board 82 are isolated from each other in the height direction (H direction in each drawing).

On the rear surface 822 of the circuit board 82, the second terminal E3112 of the inductor element 31, the second terminal E3212 of the inductor element 32, and the plurality of connection conductors 60 are mounted. This provides an electrical and physical connection between the circuit board 81 and the circuit board 82. The plurality of connection conductors 60 constitute the input-side wiring line LNi and the reference potential wiring line LNg in the circuit in FIG. 1.

Furthermore, the front surface U312 of the inductor element 31 and a front surface U322 of the inductor element 32 are flush against the rear surface 822 of the circuit board 82. As a result, the inductor element 31 and the inductor element 32 are in physical contact with the circuit board 82.

In this configuration, when the switching power supply module 10 is viewed in plan, the inductor element 31 overlaps the power semiconductor package device 21. The inductor element 32 overlaps the power semiconductor package device 22.

More specifically, the widths of the inductor elements 31 and 32 are less than or equal to the widths of the power semiconductor package devices 21 and 22. As a result, in the width direction of the switching power supply module 10, substantially the entirety of the inductor elements 31 and 32 overlaps the power semiconductor package devices 21 and 22.

The lengths of the inductor elements 31 and 32 are shorter than a length L22 of the power semiconductor package devices 21 and 22. As a result, in the length direction of the switching power supply module 10, substantially the entirety of the inductor elements 31 and 32 overlaps the power semiconductor package devices 21 and 22.

In this manner, in the present embodiment, substantially the entirety of the inductor elements 31 and 32 overlaps the power semiconductor package devices 21 and 22 in both the length and width directions.

### Example of Operational Effect of Above-Mentioned Configuration

With this configuration, the power semiconductor package devices and inductor elements that constitute a single power conversion circuit are not coplanar but are aligned in the height direction. This can reduce the planar area of a single power conversion circuit. That is, the switching power supply module 10 realizes a structure in which the circuit board 81, the plurality of inductor elements 31 and 32, and the circuit board 82 are aligned in the height direction, so that the mounting density of electronic components in a volume space can be increased.

The planar area of the switching power supply module 10 is reduced, facilitating the arrangement of the power semiconductor package devices 21 and 22 and the inductor elements 31 and 32 close to the load ZLD. This allows the switching power supply module 10 to suppress power loss when supplying power to the load ZLD.

In addition, the power semiconductor package devices 21 and 22 and the inductor elements 31 and 32 are disposed and integrated in a flat plane manner. This allows the switching power supply module 10 to have a smaller heat-generating area in plan view. Furthermore, the switching power supply module 10 can confine the heat generated by the electronic components disposed at various locations to a predetermined space volume to achieve uniform temperature distribution in the predetermined space volume. Thus, the cooling structure of the switching power supply module 10 can be simplified, and the cooling structure can suppress a reduction in heat dissipation efficiency per predetermined space volume and improve heat dissipation efficiency.

In this case, as illustrated in FIG. 2, the heat sink HS is disposed so as to overlap the power semiconductor package devices 21 and 22 and the inductor elements 31 and 32 in the switching power supply module 10, and to be flush against the power semiconductor package device 21 at the uppermost portion of the switching power supply module 10. This allows the switching power supply module 10 to dissipate heat efficiently.

Furthermore, the planar area of the heat sink HS can be made to about that of the power semiconductor package device 21, and thus the increase in the planar area of the switching power supply module 10 with the heat sink HS installed can be suppressed, and the switching power supply module 10 can be made compact.

Furthermore, in this configuration, the power semiconductor package device 21 and the inductor element 31 overlap in plan view, and the second terminal E3112 of the inductor element 31 is connected to the circuit board 82 in the vicinity of the power semiconductor package device 21 in plan view.

This allows the switching power supply module 10 to have a shorter connection distance between the power semiconductor package device 21 and the inductor element 31. Similarly, the power semiconductor package device 22 and the inductor element 32 overlap in plan view, and the second terminal E3212 of the inductor element 32 is connected to the circuit board 82 in the vicinity of the power semiconductor package device 22 in plan view. This allows the switching power supply module 10 to have a shorter connection distance between the power semiconductor package device 22 and the inductor element 32.

The inductor element 31 and the inductor element 32 are electrically and physically connected to the circuit board 81 and the circuit board 82. This allows the switching power supply module 10 to increase the rigidity of the module structure. In particular, the switching power supply module 10 can increase the rigidity of the module structure even when the switching power supply module 10 has a structure in which the circuit board 81, the plurality of inductor elements 31 and 32, and the circuit board 82 are aligned in the height direction.

Furthermore, in the switching power supply module 10, the magnetic cores 312 and 322 of the plurality of inductor elements 31 and 32 are flush against the rear surface of the circuit board 82. This allows the switching power supply module 10 to further increase the rigidity of the module structure.

Each of the inductor element 31 and the inductor element 32 is mounted in the state of a single electronic component on the circuit board 81 and the circuit board 82. In the electronic component as the inductor element 31, the main body portion 3110 is in close contact with the magnetic core 312. In the electronic component as the inductor element 32, a main body portion 3210 is in close contact with the magnetic core 322. Thus, the switching power supply module 10 can be readily manufactured even with a structure in which the circuit board 81, the plurality of inductor elements 31 and 32, and the circuit board 82 are aligned in the height direction.

In this configuration, the inductor elements 31 and 32 are connected to the circuit boards 81 and 82 by the conductor portions that extend in the direction orthogonal to the front surface of the circuit board 81 and the rear surface of the circuit board 82.

This allows a closed current path of a switching current through the inductor elements 31 and 32 to be substantially orthogonal to the electronic component mounting surfaces of the circuit boards 81 and 82.

In this case, as illustrated in FIG. 6A, a magnetic flux loop φ311E generated outside the magnetic core 312 relative to the inductor element 31 is parallel to the front surface U312 and the rear surface D312 of the magnetic core 312. Thus, as illustrated in FIG. 6B, the magnetic flux loop φ311E generated by the switching current flowing through the inductor elements 31 and 32 is substantially parallel to the mounting surfaces of the circuit boards 81 and 82. In this case, the magnetic flux loop φ311E is parallel to the mounting surfaces of the circuit boards 81 and 82, and is generated in a predetermined height range on the circuit board 81 side of the rear surface 822 of the circuit board 82. Thus, it is possible to suppress unwanted coupling between the magnetic flux loop φ311E and the electronic components mounted on the circuit boards 81 and 82 (the power semiconductor package devices 21 and 22, the plurality of capacitor elements 40, and the plurality of capacitor elements 50), the unwanted coupling adversely affecting those electronic components.

Furthermore, regarding a magnetic flux loop φ312C generated by the main body portion 3110 of the inductor element 31, magnetic flux hardly leaks outside the inductor element 31 because the magnetic core 312 is in close contact with and covers the main body portion 3110. Thus, magnetic flux does not substantially extend to the circuit boards 81 and 82 even though the magnetic flux loop φ312C generated by the main body portion 3110 is orthogonal to the mounting surfaces of the circuit boards 81 and 82. Thus, it is possible to suppress unwanted coupling between the magnetic flux loop 312C and the electronic components mounted on the circuit boards 81 and 82 (the power semiconductor package devices 21 and 22, the plurality of capacitor elements 40, and the plurality of capacitor elements 50), the unwanted coupling adversely affecting those electronic components.

In this manner, the switching power supply module 10 can control the direction of the magnetic flux generated by the switching current and suppress the degradation of characteristics while achieving high-density mounting.

The magnetic cores 312 and 322 of the inductor elements 31 and 32 include the first magnetic core portion and the second magnetic core portion with different compositions. The first magnetic core portion prioritizes the closeness of contact with the main body portion, and the second magnetic core portion prioritizes characteristics. Thus, the inductor elements 31 and 32 can suppress magnetic flux leakage and achieve excellent characteristics in a compact size.

Furthermore, the metal conductor 311 of the inductor element 31 has a larger cross-sectional area than the conductor pattern of the circuit board 82. Thus, the electrical resistance between the power semiconductor package device 21 and the inductor element 31 can be reduced. Similarly, the metal conductor 321 of the inductor element 32 has a larger cross-sectional area than the conductor pattern of the circuit board 82. Thus, the electrical resistance between the power semiconductor package device 22 and the inductor element 32 can be reduced.

In the inductor element 31, the main body portion 3110 of the metal conductor 311 and the magnetic core 312 are in close contact. In the inductor element 32, the main body portion of the metal conductor 321 and the magnetic core 322 are in close contact. As a result, in the inductor elements 31 and 32, the flux density for the generated magnetic flux can be increased by increasing the closeness of contact between the metal conductor and the magnetic core.

Thus, the inductor elements 31 and 32 can have a smaller external shape to achieve a desired inductance. This makes it easier to dispose the inductor elements 31 and 32 to overlap the power semiconductor package devices 21 and 22. Thus, in the switching power supply module 10, it becomes easier to concentrate heat-generating points in a planar manner, and heat dissipation efficiency can be improved more assuredly.

Furthermore, since the input-side wiring line LNi and the reference potential wiring line LNg are constituted by the connection conductors 60 and the connection conductors 60 are flat plates, the electrical resistances of the input-side wiring line LNi and the reference potential wiring line LNg can be reduced in the switching power supply module 10.

In this manner, the switching power supply module 10 can improve the rigidity of the module structure and is easy to manufacture, and the inductor element 31 (the inductor L31) and the inductor element 32 (the inductor L32) each have an integrated structure, in which the magnetic core encloses the metal conductor and the magnetic core and the metal conductor are in close contact with each other, and can obtain a large inductance due to a high magnetic flux distribution in the magnetic core. This allows the switching power supply module 10 to reduce conduction loss and switching loss in the switching element due to a large inductance to achieve high power conversion efficiency. Simultaneously, the switching power supply module 10 can suppress the malfunction of the control circuit against electromagnetic noise generated by the switching current due to switching operation and also suppress electromagnetic interference with the electric circuit formed on the circuit board.

### Second Embodiment

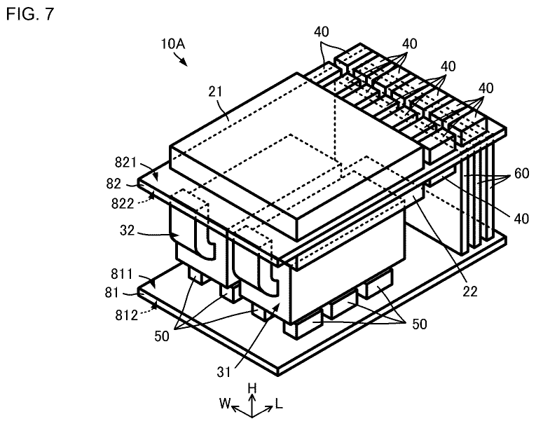

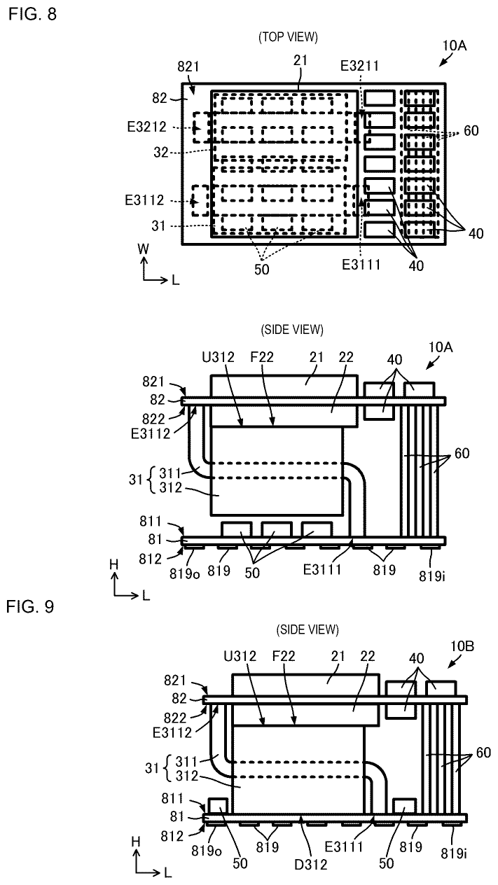

A switching power supply module according to a second embodiment of the present disclosure will be described with reference to the drawings. FIG. 7 is an external perspective view of the switching power supply module according to the second embodiment. FIG. 8 includes a top view and a side view of the switching power supply module according to the second embodiment.

A switching power supply module 10A according to the second embodiment differs from the switching power supply module 10 according to the first embodiment only in the mounting structure of the power semiconductor package devices 21 and 22 and portions related to this structure. Other configurations of the switching power supply module 10A are substantially the same as those of the switching power supply module 10, and description for substantially the same portions will be omitted.

The power semiconductor package device 22 is mounted on the rear surface 822 of the circuit board 82. The power semiconductor package device 22 is disposed closer to one end of the rear surface 822 than the plurality of capacitor elements 40 are.

When the circuit board 82 is viewed in plan, the power semiconductor package device 22 overlaps the power semiconductor package device 21.

The widths of the inductor element 31 and the inductor element 32 are less than or equal to half the widths of the power semiconductor package device 21 and the power semiconductor package device 22. When the circuit boards 81 and 82 are viewed in plan (the switching power supply module 10A is viewed in plan), the inductor elements 31 and 32 overlap the power semiconductor package devices 21 and 22.

The front surface U312 of the magnetic core 312 of the inductor element 31 and the front surface U322 of the magnetic core 322 of the inductor element 32 are flush against a front surface F22 of the power semiconductor package device 22.

This configuration allows the width of the switching power supply module 10A to be reduced to approximately half that of the switching power supply module 10. As a result, the planar area of the switching power supply module 10A can be further reduced while the switching power supply module 10A achieves substantially the same operational effects as the switching power supply module 10. The switching power supply module 10A can dissipate heat more efficiently since the electronic components that dissipate heat can be concentrated in a planar manner.

### Third Embodiment

A switching power supply module according to a third embodiment of the present disclosure will be described with reference to the drawings. FIG. 9 is a side view of the switching power supply module according to the third embodiment.

A switching power supply module 10B according to the third embodiment differs from the switching power supply module 10A according to the second embodiment in the connection structure between the inductor elements 31 and 32 and the circuit board 81. Other configurations of the switching power supply module 10B are substantially the same as those of the switching power supply module 10A, and description for substantially the same portions will be omitted.

The rear surface D312 of the magnetic core 312 of the inductor element 31 and a rear surface D322 of the magnetic core 322 of the inductor element 32 are flush against the front surface 811 of the circuit board 81.

With this configuration, the inductor element 31 and the inductor element 32 are physically connected to the circuit board 81 and the circuit board 82 over a larger area.

This allows the switching power supply module 10B to achieve higher rigidity while achieving substantially the same operational effects as the switching power supply module 10.

### Fourth Embodiment

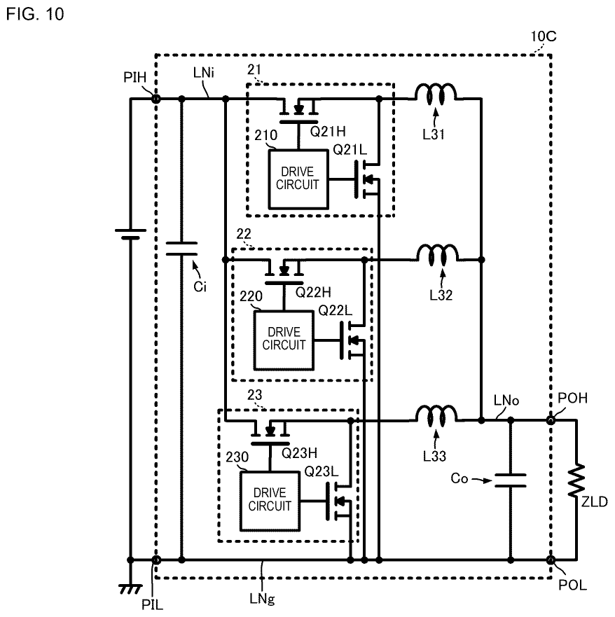

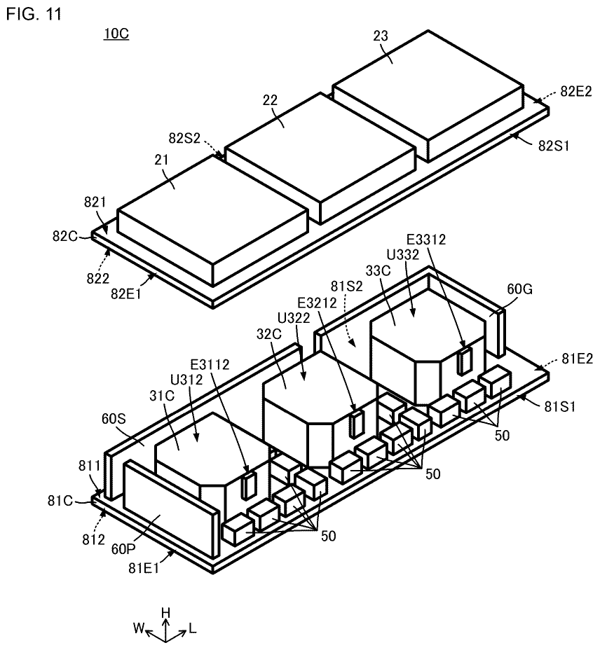

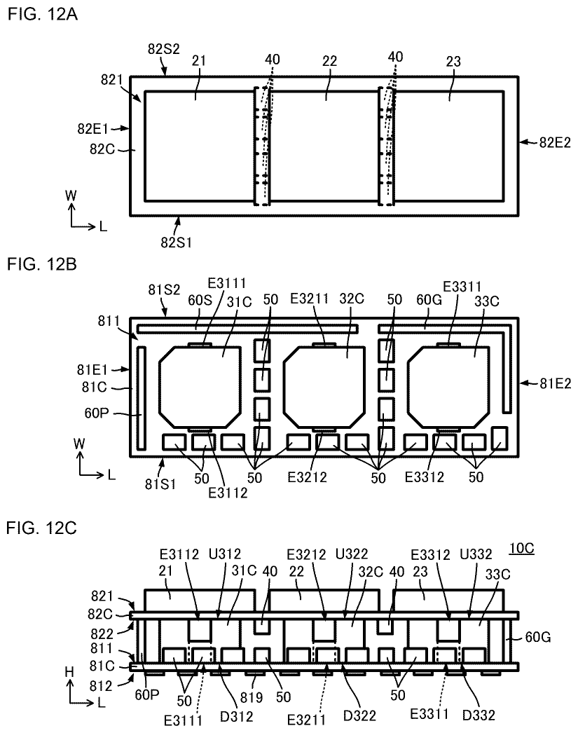

A switching power supply module according to a fourth embodiment of the present disclosure will be described with reference to the drawings. FIG. 10 is a circuit diagram of the switching power supply module according to the fourth embodiment. FIG. 11 is an exploded perspective view of the switching power supply module according to the fourth embodiment. FIG. 12A and FIG. 12B are plan views of a circuit board according to the fourth embodiment, and FIG. 12C is a side view of the switching power supply module according to the fourth embodiment.

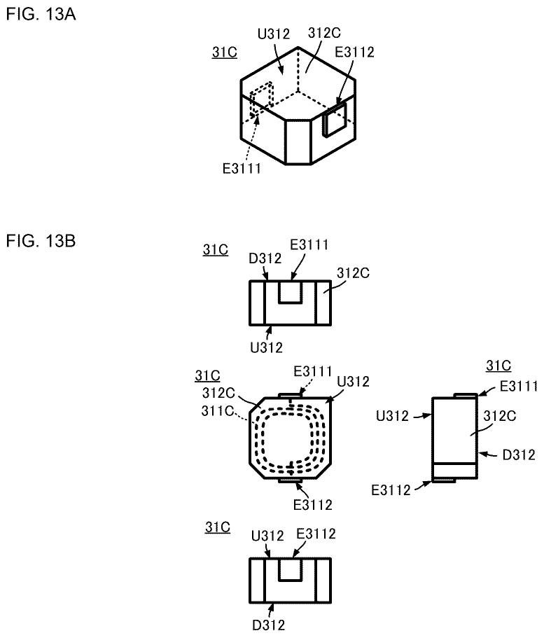

As illustrated in FIG. 10, FIG. 11, FIGS. 12A and 12B, and FIGS. 13A and 13B, a switching power supply module 10C according to the fourth embodiment differs from the switching power supply module 10 according to the first embodiment in the number of and the structure of power semiconductor package devices subjected to multiphase control. Other basic configurations of the switching power supply module 10C are substantially the same as those of the switching power supply module 10, and description for substantially the same portions will be omitted.

### (Circuit Configuration of Switching Power Supply Module 10C)

The switching power supply module 10C includes a plurality of power semiconductor package devices 21, 22, and 23 and a plurality of inductors L31, L32, and L33. The power semiconductor package device 23 has substantially the same configuration as those of the power semiconductor package devices 21 and 22, and includes a drive circuit 230, a power semiconductor device Q23H, and a power semiconductor device Q23L.

The plurality of power semiconductor package devices 21, 22, and 23 are connected in parallel to the input terminal PIH and the input terminal PIL. The output terminal of the power semiconductor package device 21 is connected to the output terminal POH with the inductor L31 interposed therebetween. The output terminal of the power semiconductor package device 22 is connected to the output terminal POH with the inductor L32 interposed therebetween. The output terminal of the power semiconductor package device 23 is connected to the output terminal POH with the inductor L33 interposed therebetween.

With this configuration, the switching power supply module 10C performs three-phase multiphase control.

### (Structure of Switching Power Supply Module 10C)

The switching power supply module 10C includes a circuit board 81C and a circuit board 82C. The circuit board 81C and the circuit board 82C are long and have substantially the same shape.

The circuit board 81C has a first end portion 81E1 at one end thereof in the longitudinal direction and has a second end portion 81E2 at the other end thereof. The circuit board 81C has a first side portion 81S1 at one end thereof in the transverse direction and has a second side portion 81S2 at the other end thereof.

The circuit board 82C has a first end portion 82E1 at one end thereof in the longitudinal direction and has a second end portion 82E2 at the other end thereof. The circuit board 82C has a first side portion 82S1 at one end thereof in the transverse direction and has a second side portion 82S2 at the other end thereof.

The plurality of power semiconductor package devices 21, 22, and 23 are mounted on a front surface 821 of the circuit board 82C. The plurality of power semiconductor package devices 21, 22, and 23 are mounted in the order of the power semiconductor package device 21, the power semiconductor package device 22, and the power semiconductor package device 23 from the first end portion 82E1 toward the second end portion 82E2.

A plurality of inductor elements 31C (L31), 32C (L32), and 33C (L33) have substantially the same configuration. FIG. 13A is an external perspective view of an inductor element according to the fourth embodiment, and FIG. 13B includes four views thereof. Note that FIGS. 13A and 13B illustrate the inductor element 31C as an example; however, the inductor elements 32C and 33C also have the same configuration.

The inductor element 31C includes a metal conductor 311C and a magnetic core 312C. The metal conductor 311 is formed in a wound shape, and at least this wound shape portion is built into the magnetic core 312. The magnetic core 312 is in close contact with the metal conductor 311.

The first terminal E3111, which is one end of the metal conductor 311, is exposed at a side surface of the magnetic core 312 and extends to the side where the rear surface D312 is present. The second terminal E3112, which is the other end of the metal conductor 311, is exposed at a side surface of the magnetic core 312 and extends to the side where the front surface U312 is present.

The plurality of inductor elements 31C, 32C, and 33C are mounted on a front surface 811 of the circuit board 81C. More specifically, the first terminal E3111 of the inductor element 31C, the first terminal E3211 of the inductor element 32C, and a first terminal E3311 of the inductor element 33C are mounted on respective land conductors on the front surface 811 of the circuit board 81C.

In this case, it is preferable that the rear surface D312 of the magnetic core 312 of the inductor element 31C, the rear surface D322 of the magnetic core 322 of the inductor element 32C, and a rear surface D332 of a magnetic core 332 of the inductor element 33C be flush against the front surface 811 of the circuit board 81C.

The plurality of inductor elements 31C, 32C, and 33C are mounted in the order of the inductor element 31C, the inductor element 32C, and the inductor element 33C from the first end portion 81E1 toward the second end portion 81E2.

When the switching power supply module 10C is viewed in plan, the inductor element 31C overlaps the power semiconductor package device 21, the inductor element 32C overlaps the power semiconductor package device 22, and the inductor element 33C overlaps the power semiconductor package device 23.

The plurality of capacitor elements 40 are mounted on a rear surface 822 of the circuit board 82C. The plurality of capacitor elements 50 are mounted on the front surface 811 of the circuit board 81C.

A connection conductor 60P, a connection conductor 60G, and a connection conductor 60S are flat plate shaped and have substantially the same configuration as the connection conductors 60. The connection conductor 60P is a connection conductor for input from the DC power supply. The connection conductor 60G is a connection conductor for the reference potential. The connection conductor 60S is a connection conductor for control signals from an external microcontroller unit (MCU) (not illustrated).

The connection conductor 60P is mounted on the front surface 811 of the circuit board 81C and in the vicinity of the first end portion 81E1. The planar surfaces of the connection conductor 60P are parallel to the first end portion 81E1 and are substantially orthogonal to the front surface 811.

The connection conductor 60G is mounted on the front surface 811 of the circuit board 81C and in the vicinity of the second end portion 81E2 and the second side portion 81S2. Part of the planar surfaces of the connection conductor 60P is parallel to the second end portion 81E2, and the remaining part of the planar surfaces of the connection conductor 60P is parallel to the second side portion 81S2. The planar surfaces of the connection conductor 60P are substantially orthogonal to the front surface 811.

The connection conductor 60S is mounted on the front surface 811 of the circuit board 81C and in the vicinity of the second side portion 81S2. The planar surfaces of the connection conductor 60S are parallel to the second side portion 81S2 and are substantially orthogonal to the front surface 811.

In this manner, the connection conductor 60P, the connection conductor 60G, and the connection conductor 60S are disposed to surround the plurality of inductor elements 31C, 32C, and 33C, except for the side where the first side portion 81S1 of the circuit board 81C is present.

In this configuration, the conductor portions of the front surface 811 of the circuit board 81C and the rear surface 822 of the circuit board 82C are electrically and physically connected by the plurality of inductor elements 31C, 32C, and 33C, the connection conductor 60P, the connection conductor 60G, and the connection conductor 60S.

More specifically, the second terminal E3112 of the inductor element 31C, the second terminal E3212 of the inductor element 32C, and a second terminal E3312 of the inductor element 33C are mounted on respective land conductors on the rear surface 822 of the circuit board 82C. In this case, it is preferable that the front surface U312 of the magnetic core 312 of the inductor element 31C, the front surface U322 of the magnetic core 322 of the inductor element 32C, and a front surface U332 of the magnetic core 332 of the inductor element 33C be flush against the rear surface 822 of the circuit board 82C.

With this configuration, the switching power supply module 10C can realize substantially the same operational effects as the switching power supply module 10.

The switching power supply module 10C includes the inductor elements 31C, 32C, and 33C using conductors formed in a wound shape, so that the planar shapes of the inductor elements 31C, 32C, and 33C for achieving inductances equivalent to those of the inductor elements 31, 32, and 33 according to the first embodiment can be reduced.

In the switching power supply module 10C, not all of the connection conductor 60P, the connection conductor 60G, and the connection conductor 60S are parallel, and are disposed so as to be spaced apart from each other. This suppresses unwanted coupling between the connection conductor 60P, the connection conductor 60G, and the connection conductor 60S.

### Fifth Embodiment

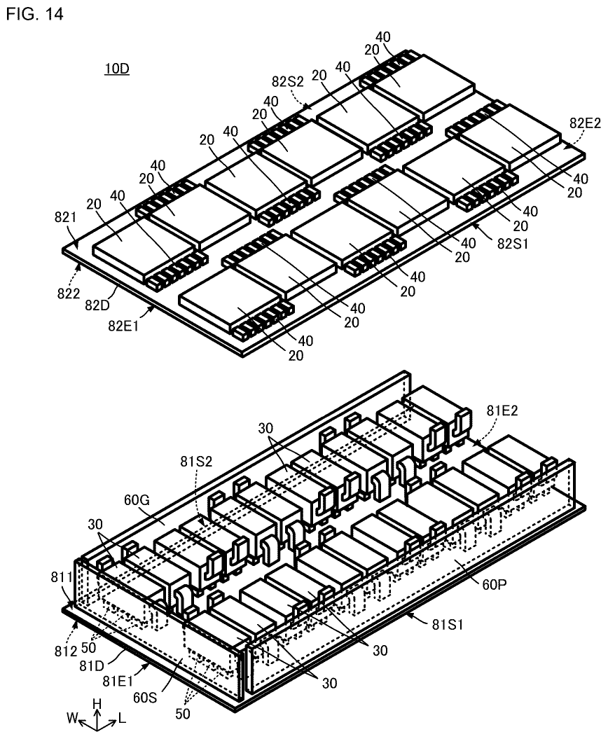

A switching power supply module according to a fifth embodiment of the present disclosure will be described with reference to the drawings. FIG. 14 is an exploded perspective view of the switching power supply module according to the fifth embodiment.

As illustrated in FIG. 14, a switching power supply module 10D according to the fifth embodiment is a 12-phase multiphase converter obtained by adopting, as appropriate, the configurations of the switching power supply modules described in the above-mentioned embodiments. Accordingly, detailed descriptions that can be readily understood from the foregoing description of the individual embodiments will be omitted below.

The switching power supply module 10D includes a circuit board 81D and a circuit board 82D. The switching power supply module 10D includes a plurality of power semiconductor package devices 20, a plurality of inductor elements 30, a plurality of capacitor elements 40, a plurality of capacitor elements 50, a connection conductor 60P, a connection conductor 60G, and a connection conductor 60S.

The plurality of power semiconductor package devices 20 have substantially the same configurations as the above-mentioned power semiconductor package device 21 and the like. The plurality of inductor elements 30 have substantially the same configurations as the above-mentioned inductor element 31.

The plurality of power semiconductor package devices 20 and the plurality of capacitor elements 40 are mounted on a front surface 821 of the circuit board 82D. Note that the plurality of power semiconductor package devices 20 and the plurality of capacitor elements 40 may be mounted not only on the front surface 821 of the circuit board 82D but also on a rear surface 822 thereof.

The plurality of inductor elements 30, the plurality of capacitor elements 50, the connection conductor 60P, the connection conductor 60G, and the connection conductor 60S are mounted on a front surface 811 of the circuit board 81D.

The plurality of inductor elements 30, the connection conductor 60P, the connection conductor 60G, and the connection conductor 60S are electrically and physically connected to the front surface 811 of the circuit board 81D and the rear surface 822 of the circuit board 82D.

With this configuration, the switching power supply module 10D enables 12-phase multiphase control and can realize substantially the same operational effects as the switching power supply module 10C.

Note that the above-mentioned embodiments are each an example, and the configurations of each embodiment can be combined as appropriate.

By combining the configurations of each embodiment of the present disclosure including the present embodiment as appropriate, a switching power supply module based on the number of power conversion circuits under multiphase control, namely a switching power supply module based on an output current value can be configured.
<1> A switching power supply module including a first circuit board on which a switching element is mounted, a second circuit board on which at least one of an input capacitor and an output capacitor is mounted, and a power inductor that electrically connects the switching element and the output capacitor. The power inductor is disposed between the first circuit board and the second circuit board. The power inductor includes a metal conductor and a magnetic core, the magnetic core encloses the metal conductor, and in an enclosed portion the metal conductor and the magnetic core are in close contact with each other to form an integrated structure. The metal conductor includes a main body portion enclosed in the magnetic core, a first end portion that is not enclosed in the magnetic core and that forms a first terminal of the power inductor at one end of the main body portion, and a second end portion that is not enclosed in the magnetic core and forms a second terminal of the power inductor at another end of the main body portion. The first end portion extends from the main body portion to the first circuit board and is physically and electrically connected to the first circuit board. The second end portion extends from the main body portion to the second circuit board and is physically and electrically connected to the second circuit board. A structure in which the first end portion of the power inductor is connected to the first circuit board and a structure in which the second end portion is connected to the second circuit board constitute a three-dimensional structure in which a volumetric packing density of electronic components is increased. Also, increase a mounting density of electronic components in a volume space by causing a closed current path through which a switching current flows to be substantially orthogonal to the first circuit board and the second circuit board and causing a magnetic flux loop generated by the switching current to be substantially parallel to the first circuit board and the second circuit board, and control a direction of magnetic flux generated by the switching current.
<2> The switching power supply module according to <1>, in which a direction in which the main body portion extends is parallel to the first circuit board and the second circuit board.
<3> The switching power supply module according to <1> or <2>, in which the magnetic core includes a first magnetic core portion, which is in close contact with the metal conductor, and a second magnetic core portion, which is spaced apart from the metal conductor and is in close contact with the first magnetic core portion.
<4> The switching power supply module according to <3>, in which the first magnetic core portion and the second magnetic core portion have different material compositions and are formed as a single unit using magnetic materials having different compositions.
<5> The switching power supply module according to any one of <1> to <4>, in which the switching element includes a plurality of switching elements, and the plurality of switching elements are mounted on both surfaces of the first circuit board at different positions from each other.
<6: The switching power supply module according to <5>, in which the power inductor includes a plurality of power inductors equal in number to the switching elements, and the plurality of power inductors are aligned and disposed parallel to the first circuit board and the second circuit board.
<7> The switching power supply module according to <6>, in which when viewed in a direction in which the first circuit board, the plurality of power inductors, and the second circuit board are aligned, the magnetic cores of the plurality of power inductors are each disposed to overlap a corresponding one of the plurality of power inductors.
<8> The switching power supply module according to any one of <1> to <7>, in which the switching element includes a power semiconductor integrated circuit that is obtained by forming a power semiconductor device and a drive circuit as a single unit.
<9> The switching power supply module according to any one of <1> to <8>, in which the input capacitor is mounted on the first circuit board.
<10> The switching power supply module according to any one of <1> to <9>, in which the output capacitor is mounted on the second circuit board.
<11> The switching power supply module according to any one of <1> to <10>, in which the power inductor and at least one of the input capacitor and the output capacitor are mounted on a front surface of the second circuit board, and land conductors arranged in a two-dimensional array are formed on a rear surface of the second circuit board.
<12> The switching power supply module according to any one of <1> to <11>, including a connecting member that electrically and physically connects a front surface of the second circuit board and a rear surface of the first circuit board. The connecting member is a busbar whose main material is metal or a wiring circuit board obtained by forming a conductor pattern on substantially the entire surface of an insulating substrate.
<13> The switching power supply module according to <6> or <7>, including a plurality of power conversion circuits each including the switching element and the power inductor, and a control unit that controls operation of the plurality of power conversion circuits. The control unit performs a multiphase converter operation by shifting the phases of operation of the plurality of power conversion circuits.

What is claimed is:

1. A switching power supply module comprising:
a first circuit board on which a switching element is mounted;
a second circuit board on which at least one of an input capacitor and an output capacitor is mounted; and
a power inductor that electrically connects the switching element and the output capacitor, wherein
the power inductor is between the first circuit board and the second circuit board,
the power inductor includes a metal conductor and a magnetic core, the magnetic core encloses the metal conductor, and in an enclosed portion the metal conductor and the magnetic core are in close contact with each other to configure an integrated structure,
the metal conductor includes
a main body portion enclosed in the magnetic core,
a first end portion that is not enclosed in the magnetic core and that configures a first terminal of the power inductor at one end of the main body portion, and
a second end portion that is not enclosed in the magnetic core and configures a second terminal of the power inductor at another end of the main body portion,
the first end portion extends from the main body portion to the first circuit board and is physically and electrically connected to the first circuit board,
the second end portion extends from the main body portion to the second circuit board and is physically and electrically connected to the second circuit board, and
a structure in which the first end portion of the power inductor is connected to the first circuit board and a structure in which the second end portion is connected to the second circuit board
configure a three-dimensional structure in which a volumetric packing density of electronic components is increased, and
increase a mounting density of electronic components in a volume space by causing a closed current path through which a switching current flows to be substantially orthogonal to the first circuit board and the second circuit board and causing a magnetic flux loop generated by the switching current to be substantially parallel to the first circuit board and the second circuit board, and control a direction of magnetic flux generated by the switching current.

2. The switching power supply module according to claim 1, wherein
a direction in which the main body portion extends is parallel to the first circuit board and the second circuit board.

3. The switching power supply module according to claim 1, wherein
the magnetic core includes a first magnetic core portion, which is in close contact with the metal conductor, and a second magnetic core portion, which is spaced apart from the metal conductor and is in close contact with the first magnetic core portion.

4. The switching power supply module according to claim 3, wherein
the first magnetic core portion and the second magnetic core portion have different material compositions and are formed as a single unit using magnetic materials having different compositions.

5. The switching power supply module according to claim 1, wherein
the switching element includes a plurality of switching elements, and
the plurality of switching elements are mounted on both surfaces of the first circuit board at different positions from each other.

6. The switching power supply module according to claim 5, wherein
the power inductor includes a plurality of power inductors equal in number to the switching elements, and
the plurality of power inductors are aligned, and are parallel to the first circuit board and the second circuit board.

7. The switching power supply module according to claim 6, wherein
when viewed in a direction in which the first circuit board, the plurality of power inductors, and the second circuit board are aligned,
the magnetic cores of the plurality of power inductors each overlap a corresponding one of the plurality of power inductors.

8. The switching power supply module according to claim 1, wherein
the switching element includes a power semiconductor integrated circuit that is configure by a power semiconductor device and a drive circuit as a single unit.

9. The switching power supply module according to claim 1, wherein
the input capacitor is mounted on the first circuit board.

10. The switching power supply module according to claim 1, wherein
the output capacitor is mounted on the second circuit board.

11. The switching power supply module according to claim 1, wherein
the power inductor and at least one of the input capacitor and the output capacitor are mounted on a front surface of the second circuit board, and
land conductors arranged in a two-dimensional array are on a rear surface of the second circuit board.

12. The switching power supply module according to claim 1, comprising:
a connecting member that electrically and physically connects a front surface of the second circuit board and a rear surface of the first circuit board,
wherein the connecting member is a busbar whose main material is metal or a wiring circuit board configured as a conductor pattern on substantially the entire surface of an insulating substrate.

13. The switching power supply module according to claim 6, comprising:
a plurality of power conversion circuits each including the switching element and the power inductor; and
a control unit configured to control operation of the plurality of power conversion circuits,
wherein the control unit is configured to perform a multiphase converter operation by shifting the phases of operation of the plurality of power conversion circuits.

14. The switching power supply module according to claim 2, wherein
the magnetic core includes a first magnetic core portion, which is in close contact with the metal conductor, and a second magnetic core portion, which is spaced apart from the metal conductor and is in close contact with the first magnetic core portion.

15. The switching power supply module according to claim 2, wherein
the switching element includes a plurality of switching elements, and
the plurality of switching elements are mounted on both surfaces of the first circuit board at different positions from each other.

16. The switching power supply module according to claim 2, wherein
the switching element includes a power semiconductor integrated circuit that is configure by a power semiconductor device and a drive circuit as a single unit.

17. The switching power supply module according to claim 2, wherein
the input capacitor is mounted on the first circuit board.

18. The switching power supply module according to claim 2, wherein
the output capacitor is mounted on the second circuit board.

19. The switching power supply module according to claim 2, wherein
the power inductor and at least one of the input capacitor and the output capacitor are mounted on a front surface of the second circuit board, and
land conductors arranged in a two-dimensional array are on a rear surface of the second circuit board.

20. The switching power supply module according to claim 2, comprising:
a connecting member that electrically and physically connects a front surface of the second circuit board and a rear surface of the first circuit board,
wherein the connecting member is a busbar whose main material is metal or a wiring circuit board configured as a conductor pattern on substantially the entire surface of an insulating substrate.
